(19) United States
(12) Patent Application Publication
(10) Pub. No.: US 2015/0279771 A1
(43) Pub. Date: Oct. 1, 2015

(54) SEMICONDUCTOR PACKAGE AND MANUFACTURING METHOD THEREOF

(71) Applicant: ChipMOS Technologies Inc., Hsinchu (TW)

(72) Inventor: Chien-Chih HUANG, Hsinchu (TW)

(21) Appl. No.: 14/642,122

(22) Filed: Mar. 9, 2015

(30) Foreign Application Priority Data
Mar. 31, 2014 (TW) 103111955

(51) Int. Cl. H01L 23/498; H01L 23/00; H01L 21/48; H01L 23/31; H01L 21/56

(52) U.S. Cl. CPC H01L 23/49827; H01L 23/3107; H01L 21/56; H01L 21/486; H01L 24/83; H01L 24/32; H01L 21/568; H01L 24/16; H01L 2224/83192; H01L 2224/83851; H01L 2224/8389; H01L 2224/83874; H01L 2224/83862; H01L 2224/83855; H01L 2224/32235

(57) ABSTRACT

A semiconductor package and manufacturing method thereof are disclosed. The semiconductor package includes a photosensitive conductive layer, a chip and an encapsulant. The photosensitive conductive layer includes at least one electrically conductive portion and at least one insulating portion. The chip is disposed on the photosensitive conduct layer and electrically coupled the least one electrically conductive portion. The encapsulant covers the chip and the photosensitive conductive layer.

### CROSS REFERENCE TO RELATED APPLICATION

This application claims priority to Taiwan Patent Document No. 103111955, filed on Mar. 31, 2014 with the Taiwan Patent Office, which is incorporated by reference in its entirety.

### BACKGROUND OF THE INVENTION

1. Field of the Invention

The present invention relates to a semiconductor package and manufacturing method thereof, and more particularly, to a semiconductor package and manufacturing method thereof using a photosensitive conductive material as a circuit layer.

2. Description of the Prior Art

With the rapid development of technology, the semiconductor packaging technology and materials change rapidly as well. As the integration density of the semiconductor wafer increases, the pin number and density of the semiconductor package increase accordingly. To meet the requirement for high pin counts, many semiconductor packages would use high-density printed circuit substrates as the package carriers. The conventional punted circuit substrate is usually constructed by famine, build-up layers which include several metal layers and insulating layers alternately laminated on a core substrate, wherein the metal layers are patterned through photolithography and etching process. Therefore, the manufacturing process of the conventional printed circuit substrate is complex and time consuming, and the thickness of the printed circuit substrate can not be decreased effectively. Hence, simplification of the manufacturing process and reduction of the manufacturing cost are always the subject of continuous improvement in this field.

### SUMMARY OF THE INVENTION

An object of the present invention is to provide a semiconductor packaging method comprising the following steps: providing a carrier, the carrier having a first surface and a second surface opposite to the first surface; forming a photosensitive conductive material on the first surface of the carrier; exposing the photosensitive conductive material to form a photosensitive conductive layer, the photosensitive conductive layer comprising at least one electrically conductive portion and at least one insulating portion; disposing a chip on the photosensitive conductive layer; electrically coupling the chip to the at least one electrically conductive portion; forming an encapsulant to cover the chip and the photosensitive conductive layer; and forming at least one conductive via in the carrier, wherein the at least one conductive via is electrically coupled to the at least one electrically conductive portion.

Another object of the present invention is to provide a semiconductor packaging method comprising the following steps: providing a carrier; forming a photosensitive conductive material on a surface of the carrier; exposing the photosensitive conductive material to form a photosensitive conductive layer, the photosensitive conductive layer comprising at least one electrically conductive portion and at least one insulating portion; disposing a chip on the photosensitive conductive layer; electrically coupling the chip to the at least one electrically conductive portion; forming an encapsulant to cover the chip and the photosensitive conductive layer; and removing the carrier.

Yet another object of the present invention is to provide a semiconductor packaging method comprising the following steps: providing a carrier, the carrier having a first surface, a second surface opposite to the first surface and at least one through hole; forming a photosensitive conductive material on the first surface of the carrier; exposing the photosensitive conductive material to harm a photosensitive conductive layer, the photosensitive conductive layer comprising at least one electrically conductive portion and at least one insulating portion, and the through hole being correspondingly coupled to the at least one electrically conductive portion; disposing a chip on the photosensitive conductive layer; electrically coupling the chip to the at least one electrically conductive portion; and forming an encapsulant to cover the chip and the photosensitive conductive layer.

Still another object of the present invention is to provide a semiconductor package comprising a carrier having a first surface and a second surface opposite to the first surface, a photosensitive conductive layer configured on the first surface of the carrier and comprising at least one electrically conductive portion and at least one insulating, portion, a chip disposed on the photosensitive conductive layer and electrically coupled to the at least one electrically conductive portion, an encapsulant covering the chip and the photosensitive conductive layer, and at least one conductive via configured in the carrier and electrically coupled to the at least one electrically conductive portion.

Still another object of the present invention is to provide a semiconductor package comprising a photosensitive conductive layer comprising at least one electrically conductive portion and at least one insulating portion, a chip disposed on the photosensitive conductive layer and electrically coupled to the at least one electrically conductive portion, and an encapsulant covering the chip and the photosensitive conductive layer.

The advantages and spirits of the invention may be understood by the following recitations together with the appended drawings.

### BRIEF DESCRIPTION OF THE APPENDED DRAWINGS

Some of the embodiments will be described in detail, with reference to the following figures, wherein like designations denote like members, wherein:

FIG. 1 to FIG. 5 show the sectional drawings of each step of a semiconductor packaging method, according to an embodiment of the present invention.

FIG. 5A and FIG. 5B show the sectional drawings of another manufacturing process after the step in FIG. 4 of a semiconductor packaging method, according to another embodiment of the present invention.

FIG. 6 shows the sectional drawing of a semiconductor package, according to another embodiment of the present invention.

FIG. 7 to FIG. 10 show the sectional drawings of each step of a semiconductor packaging method, according to another embodiment of the present invention.

### DETAILED DESCRIPTION OF THE INVENTION

A detailed description of the hereinafter described embodiments of the disclosed apparatus and method are presented herein by way of exemplification and not limitation with reference to the Figures. Although certain embodiments are shown and described in detail, it should be understood that various changes and modifications may be made without departing from the scope of the appended claims. The scope of the present invention will in no way be limited to the number of constituting components, the materials thereof, the shapes thereof, the relative arrangement thereof, etc., and are disclosed simply as an example of embodiments of the present invention.

Please refer to FIG. 1 to FIG. 5, which show the sectional drawings of each step of a semiconductor packaging method, according to an embodiment of the present invention. Referring to FIG. 1, the packaging method of the present invention is performed on a carrier 100, wherein the carrier 100 has a first surface 100A and a second surface 100B opposite to the first surface 100A. The carrier 100 may be made of any material, such as metals, insulating materials, semiconductor materials, or composite materials composed of the aforesaid materials. In this embodiment, the carrier 100 is made of an insulating material, such as epoxy resin, polyimide, glass, etc. Next, a photosensitive conductive material 102 is formed on the first surface 100A of the carrier 100.

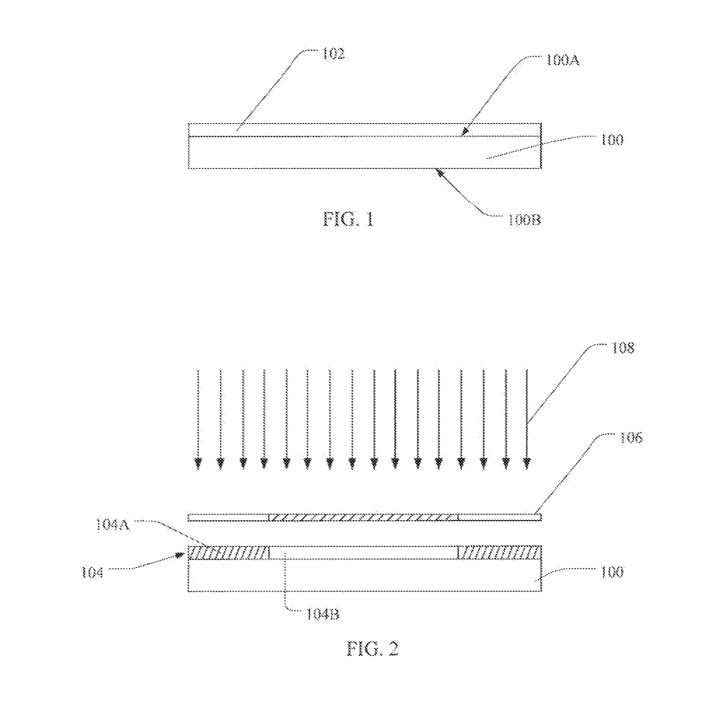

Referring to FIG. 2. photosensitive conductive material 102 is then exposed oil to form a photosensitive conductive layer 104. For example, a light source 108 irradiates a part of the photosensitive conductive material 102 through a mask 106 having wiring patterns so as to expose the photosensitive conductive material 102 to form a photosensitive conductive layer 104 having at least one electrically conductive portion 104A and at least one insulating portion 104B. The light source 108 can be ultraviolet, X-ray, or other applicable light sources. After the photosensitive conductive material 102 is irradiated by the light source 108, a part becomes electrically conductive forming the electrically conductive portion 104A. One skilled in the art should know that besides using mask 106 for exposure, the process can be performed by applying direct write lithography so that the patterns are written on the photosensitive conductive material 102 directly by a light beam, in which the mask 106 is not necessary. More particularly, the method for forming the photosensitive conductive material 102 can be first coating the photosensitive conductive material 102 on the first surface 100A of the carrier 100, then thermal curing the photosensitive conductive material 102 followed by exposing the photosensitive conductive material 102 with ultraviolet or X-ray. In another embodiment of the present invention, the photosensitive conductive material 102 can be formed on the first surface 100A of the carrier 100 by the method of film attaching, and then cured by light simultaneously during the exposure of the photosensitive conductive material 102.

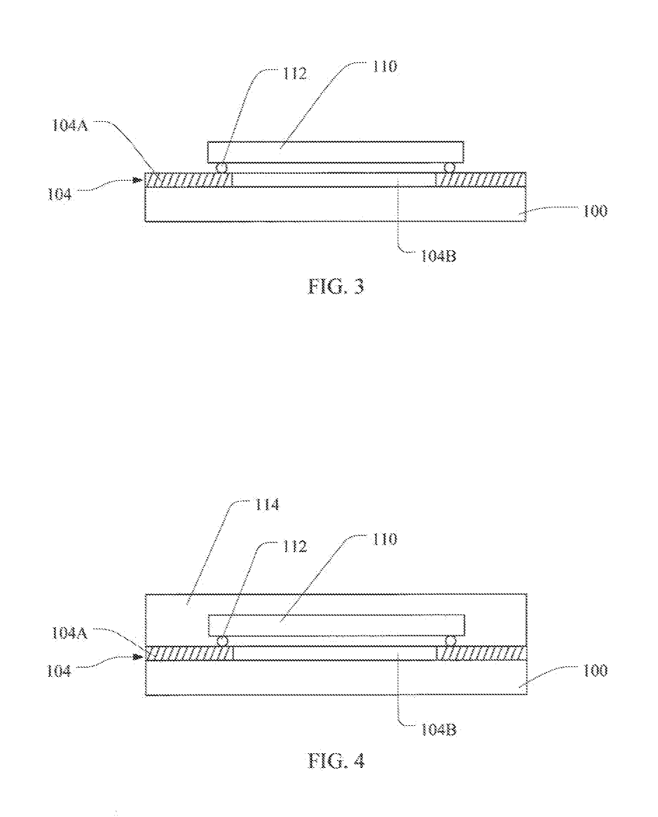

Please refer to FIG. 3. A chip 110 is they disposed on the photosensitive conductive layer 104, and electrically coupled to the electrically conductive portion 104A, for example, by flip chip bonding, where the bonding pads (not shown in figure) of the chip 110 are electrically coupled to the electrically conductive portion 104A through conductive bumps 112. Next, referring to FIG. 4, an encapsulant 114 is formed to cover the chip 110, the conductive bumps 112, and the photosensitive conductive layer 104. The encapsulant 114 can be made of epoxy resin, it is worth noting that before forming the encapsulant 114, an underfill can be formed inbetween the chip 110 and the photosensitive conductive layer 104 optionally to protect the conductive bumps 112.

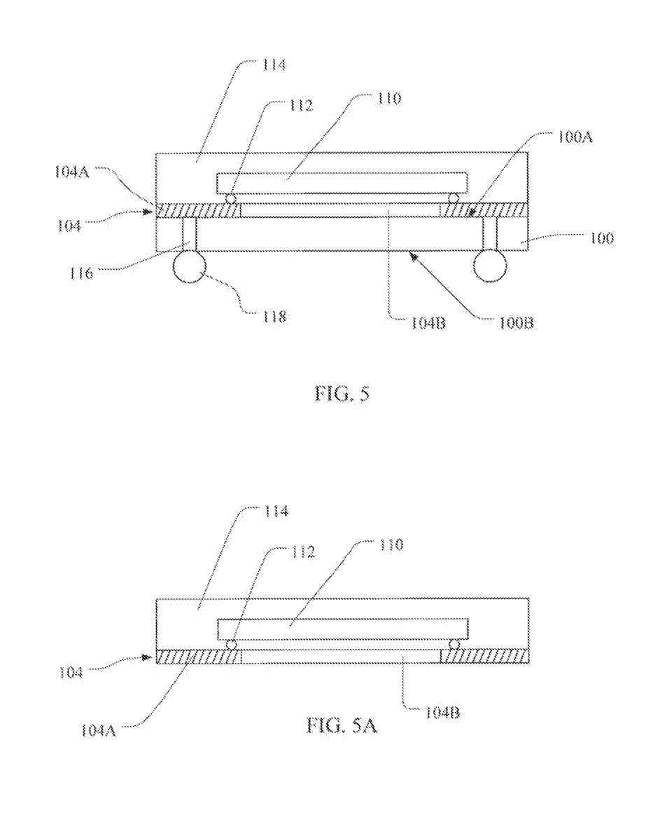

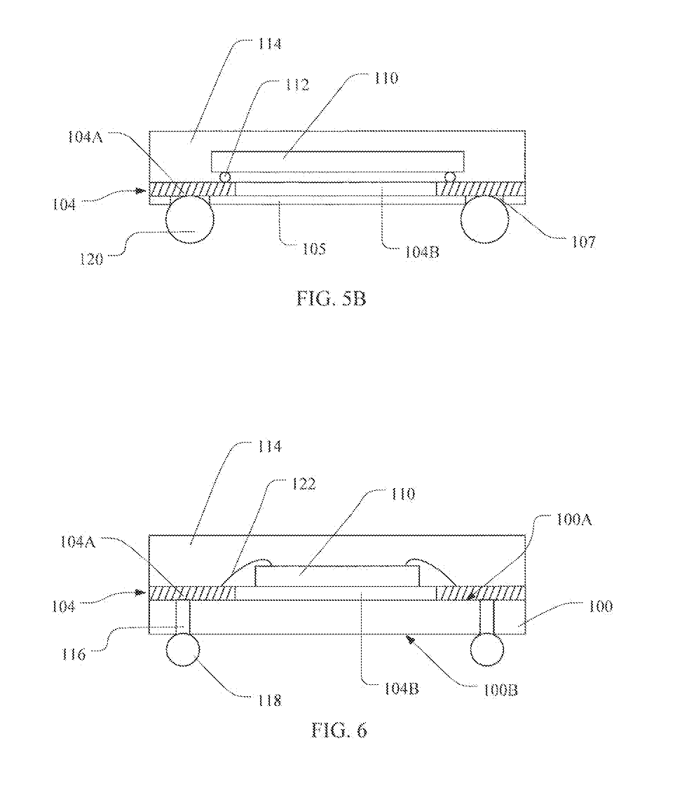

Please refer to FIG. 5. The conductive vias 116 are formed in the carrier 100, wherein the conductive vias 116 are electrically coupled to the electrically conductive portion 104A. More particularly, the conductive vias 116 can be formed by first forming through holes in the carrier 100, for example, by the method of drilling or photolithography, and then tilling a conductive material such as solder into the through holes. After forming the conductive vias 116 in the carrier 100, external terminals 118 such as solder balls can be formed on the second surface 100B of the carrier 100 optionally. The external terminals 118 are electrically coupled to the conductive vias 116 serving as outer connections, for example, the connection points for surface mounting.

Please refer to FIG. 5A and FIG. 5B. FIG, which show the sectional drawings of another manufacturing process after the step in FIG. 4 of a semiconductor packaging method, according to another embodiment of the present invention. In another embodiment of the present invention, after forming the encapsulant 114 as shown in FIG. 4, the carrier 100 can be removed forming the structure as shown in FIG. 5A, in which the photosensitive conductive layer 104 is exposed. Then, referring to FIG. 5B, the external terminals 120 such as solder balls can be formed on the electrically conductive portion 104A of the photosensitive conductive layer 104 optionally, and electrically coupled to the electrically conductive portion 104A to serve as outer connections, for example, the connection points for surface mounting. It is worth noting that for the semiconductor package of this embodiment, since the photosensitive conductive layer 104 is exposed to outside environment, it is preferably to use the photosensitive conductive material exposable to X-ray to form the photosensitive conductive layer 104 so as to prevent the photosensitive conductive material from being reacted due to natural ultraviolet light, which may alter the electrical conductivity property. In addition, a patterned solder mask layer 105 can also be formed on the exposed surface of the photosensitive conductive layer 104. The patterned solder mask layer 105 has at least one opening 107 to expose a part of the electrically conductive portion 104A. The external terminal 120 can then be formed in the opening 107. Or if the semiconductor package of the present invention can be well shielded or covered to prevent the irradiation of natural ultraviolet light during its application, a UV-exposable photosensitive conductive material can also be used.

Please refer to FIG. 6, which shows the sectional drawing of a semiconductor package, according to another embodiment of the present invention. Referring to FIG. 5 and FIG. 6, the difference between FIG. 5 and FIG. 6 is that the chip 110 is flip-chip bonded to the electrically conductive portion 104A via conductive bumps 112 in FIG. 5, but in FIG. 6 the chip 110 is attached to the photosensitive conductive layer 104 with the rear surface of the chip 110, for example, by using an adhesive (not shown in FIG. 6), and wire-bonded to electrically couple the bonding pads (not shown in FIG. 6) on the active surface of the chip 110 to the electrically conductive portion 104A through bonding wires 122.

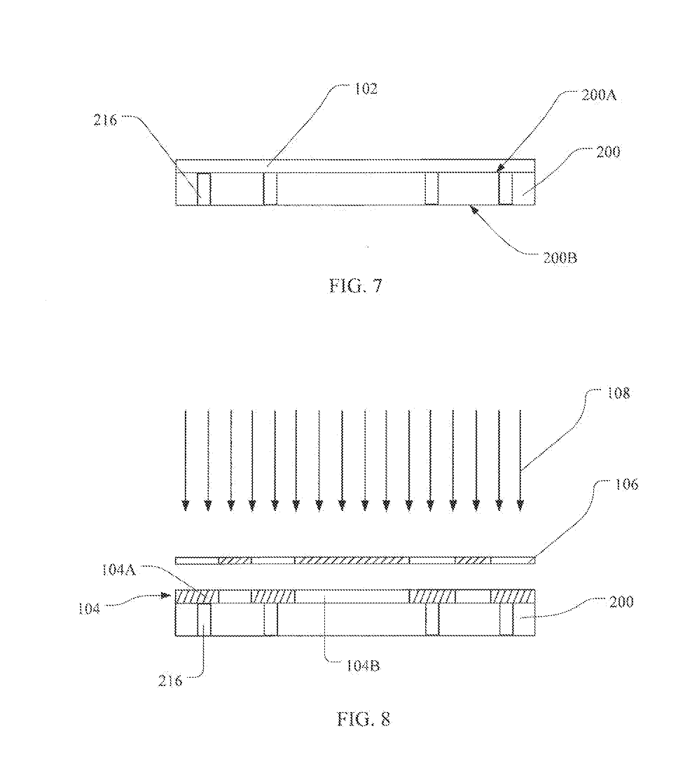

Please refer to FIG. 7 to FIG. 10, which show the sectional drawings of each step of a semiconductor packaging method, according to another embodiment of the present invention. Referring to FIG. 7, the packaging method of the present invention is performed on a carrier 200, wherein the carrier 200 has a first surface 200A and a second surface 200B opposite to the first surface 200A. In this embodiment, the carrier 200 is made of an insulating material, such as epoxy resin, polyimide, glass, etc., and the through holes 216 have been thrilled in the carrier 200. A photosensitive conductive material 102 is then formed on the first surface 200A of the carrier 200.

Referring to FIG. 8, the photosensitive conductive, material 102 is exposed to form a photosensitive conductive layer 104. For example, a light source 108 irradiates a part of the photosensitive conductive material 102 through a mask 106 having wiring patterns so as to expose the photosensitive conductive material 102 to form a photosensitive conductive layer 104 including at least one electrically conductive portion 104A and at least one insulating portion 104B. The light source 108 can be ultraviolet, X-ray, or other applicable light, sources. After the photosensitive conductive material 102 is irradiated by the light source 108, a part becomes electrically conductive forming the electrically conductive portion 104A, wherein the through holes 216 ale correspondingly coupled to the electrically conductive portion 104A respectively. One skilled in the art should know that besides using mask 106 for exposure, the process can be performed by applying direct write lithography so that the patterns are written on the photosensitive conductive material 102 directly by a light beam, in which the mask 106 is not necessary. More particularly, the method for forming the photosensitive conductive material 102 can be first coating the photosensitive conductive material 102 on the first surface 200A of the carder 200, then thermal curing the photosensitive conductive material 102 followed by exposing the photosensitive conductive material 102 with ultraviolet or X-ray. In another embodiment of the present invention, the photosensitive conductive material 102 can be formed on the first surface 200A of the carrier 200 by the method of film attaching, and then cured by light simultaneously during the exposure of the photosensitive conductive material 102.

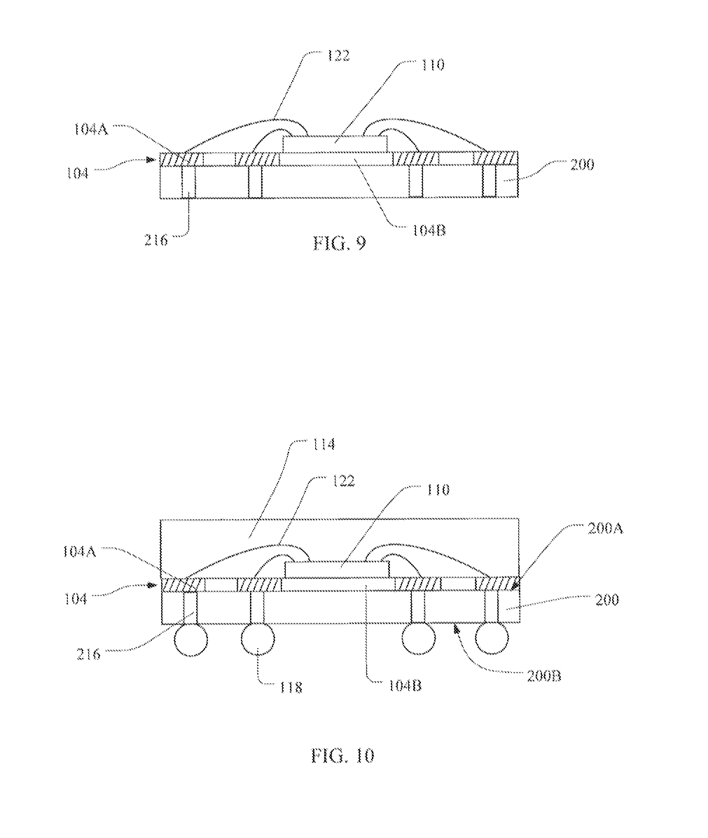

Referring to FIG. 9, a chip 110 is then disposed on the photosensitive conductive layer 104, and electrically coupled to the electrically conductive portion 104A. More particularly, the chip 110 is attached to the photosensitive conductive layer 104 with the rear surface of the chip 110, for example, by using an adhesive mot shown in FIG. 9), and wire-bonded to electrically couple the bonding pads (not shown in PIG. 9) on the active surface of the chip 110 to the electrically conductive portion 104A. through bonding wires 122. Next, referring to FIG. 10, an encapsulant 114 is formed to cover the chip 110, the bonding wires 122, and the photosensitive conductive layer 104. The encapsulant 114 can be made of epoxy resin. Finally, the external terminals 118 such as solder balls can be formed on the second surface 200B of the carrier 200 optionally. The external terminals 118 are electrically coupled to the electrically conductive portion 104A is the through holes 216, serving as outer connections, for example, the connection points it surface mounting.

It is worth noting that the through holes 216 in this embodiment also comprise a conductive material for electrical connection, wherein the conductive material can be formed by the following methods. First, when coating the photosensitive conductive material 102 on the first surface 200A of the carrier 200, the photosensitive conductive material 102 is also filled into the through holes 216. Through the step of exposure, the photosensitive conductive material 102 filled in the through holes 216 is exposed to form a part of the electrically conductive portion 104A as well. Second, when providing the carrier 200, the through holes 216 have been filled with a conductive material such as solder. That is to say the carrier 200 can be a printed circuit substrate with the wiring circuits and/or conductive vias already formed therein. Third, when forming the external terminals 118 on the second surface 200B of the carrier 200 a conductive material is also filled into the through holes 216. For example, when forming solder balls/solder pads, the solder material is also filled into the through holes 216.

In summary, the semiconductor package substrate of the present invention is a circuit layer formed directly by exposing the photosensitive conductive material to form the wiring region (i.e. the electrically conductive portion) and the insulating region (i.e. the insulating portion) used for holding the wiring region, which omits the steps of development and etching. Thus, the manufacturing process can be simplified and the cost can be reduced. Moreover, the decreased thickness of the package substrate can further lead to thinness of the semiconductor package.

With the examples and explanations mentioned above, the features and spirits of the invention are hopefully well described. More importantly, the present invention is not limited to the embodiment described herein. Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A semiconductor for packaging method, comprising:
providing a carrier, the carrier having a first surface and a second surface opposite to the first surface;
forming a photosensitive conductive material on the first surface of the carrier;
exposing the photosensitive conductive material to form a photosensitive conductive layer, the photosensitive conductive layer comprising at least one electrically conductive portion and at least one insulating portion;
disposing a chip on the photosensitive conductive layer;
electrically coupling the chip to the at least one electrically conductive portion;
forming an encapsulant to cover the chip and time photosensitive conductive layer; and
forming at least one conductive via in the carrier, wherein the at least one conductive via is electrically coupled to the at least one electrically conductive portion.

2. The semiconductor packaging method of claim 1, further comprising forming at least one external terminal on the second surface of the carrier after forming the at least one conductive via in the carrier, wherein the at least one external terminal is electrically coupled to the at least one conductive via.

3. The semiconductor packaging method of claim 1, wherein the step of forming the photosensitive conductive material further comprises:
coating the photosensitive conductive material on the first surface of the carrier; and
thermal curing the photosensitive conductive material.

4. The semiconductor packaging method of claim 1, wherein the step of exposing the photosensitive conductive material comprises using ultraviolet or X-ray to expose the photosensitive conductive material.

5. A semiconductor packaging method, comprising;
providing a carrier;
forming a photosensitive conductive material on a surface of the carrier;
exposing the photosensitive conductive material to form a photosensitive conductive layer, the photosensitive conductive layer comprising at least one electrically conductive portion and at least one insulating portion;
disposing a chip on the photosensitive conductive layer;
electrically coupling the chip to the at least one electrically conductive portion;
forming an encapsulant to cover the chip and the photosensitive conductive layer; and
removing the carrier.

6. The semiconductor packaging method of claim 5, further comprising forming at least one external terminal after removing the carrier, wherein the at least one external terminal is electrically coupled to the at least one electrically conductive portion.

7. The semiconductor packaging method of claim 5, wherein the step of forming the photosensitive conductive material for further comprises;
coating the photosensitive conductive material on the surface of the carrier; and
thermal curing the photosensitive conductive material.

8. The semiconductor packaging method of claim wherein the step of exposing the photosensitive conductive material comprises using ultraviolet or X-ray to expose the photosensitive conductive material.

9. A semiconductor packaging method, comprising:
providing a carrier, the carrier having a first surface, a second surface opposite to the first surface and at least one through hole;
forming a photosensitive conductive material on the first surface of the carrier;
exposing the photosensitive conductive material to form a photosensitive conductive layer, the photosensitive conductive layer comprising at least one electrically conductive portion and at least one insulating portion, and the through hole being correspondingly coupled to the at least one electrically conductive portion;
disposing a chip on the photosensitive conductive layer;
electrically coupling the chip to the least one electrically conductive portion; and
forming an encapsulant to cover the chip and the photosensitive conductive layer.

10. The semiconductor packaging method of claim 9, further comprising forming at least one external terminal on the second surface of the carrier after forming the encapsulant wherein the at least one external terminal is electrically coupled to the at least one electrically conductive portion.

11. The semiconductor packing method of claim 9, wherein the step of forming the photosensitive conductive material further comprises:
coating the photosensitive conductive material on the first surface of the carrier; and
thermal curing the photosensitive conductive material.

12. The semiconductor packaging method of claim 9, wherein the step of exposing the photosensitive conductive material comprises using ultraviolet or X-ray to expose the photosensitive conductive material.

13. The semiconductor packaging method of claim 11, wherein when coating the photosensitive conductive material on the first surface of the carrier, the photosensitive conductive material is also filled into the at least one through hole, and the at least one electrically conductive portion includes the photosensitive conductive material filled in the at least one through hole.

14. The semiconductor packaging method of claim 9, wherein in the step of providing the carrier, the at least one through hole is filled with a conductive material.

15. The semiconductor packaging method of claim 10, wherein the step of forming the external terminal on the second surface of the carrier further comprises filling a conductive material into the through hole.

16. A semiconductor package, comprising;
a carrier, having a first surface and a second surface opposite to the first surface;
a photosensitive conductive layer, configured on the first surface of the carrier, the photosensitive conductive layer comprising at least one electrically conductive portion and at least one insulating portion;
a chip, disposed on the photosensitive conductive layer and electrically coupled to the at least one electrically conductive portion;
an encapsulant covering the chip and the photosensitive conductive layer; and
at least one conductive via, configured in the carrier and electrically coupled to the at least one electrically conductive portion.

17. The semiconductor package of claim 16, further comprising at least one external terminal configured on the second surface of the carrier and electrically coupled to the conductive via.

18. The semiconductor package of claim 16, wherein the at least one electrically conductive portion is formed by using ultraviolet or X-ray to expose the photosensitive conductive material.

19. A semiconductor package, comprising:
a photosensitive conductive layer, comprising at least one electrically conductive portion and at least one insulating portion;
as chip, disposed on the photosensitive conductive layer and electrically coupled to the at least one electrically conductive portion; and
an encapsulant, covering the chip and the photosensitive conductive layer.

20. The semiconductor package of claim 19, further comprising at least one external terminal, wherein the at least one external terminal is electrically coupled to the at least one electrically conductive portion.

21. The semiconductor package of claim 19, wherein the at least one electrically conductive portion is formed by using ultraviolet or X-ray to expose the photosensitive conductive material.
